(19) United States
(12) Patent Application Publication
(10) Pub. No.: US 2003/0047743 A1
(43) Pub. Date: Mar. 13, 2003

(54) Semiconductor light emitting device

(76) Inventor: Gang Li, Taipei City (TW)

Correspondence Address: Gang LI, PO Box 82-144, TAIPEI, TW

(21) Appl. No.: 09/946,612

(22) Filed: Sep. 4, 2001

(51) Int. Cl. H01L 33/00

(52) U.S. Cl. 257/96; 257/79; 257/97; 257/80

(57) ABSTRACT

A gallium nitride-based compound semiconductor light emitting element has compound semiconductor layers including a first conductivity type compound semiconductor layer and a second conductivity type compound semiconductor layer formed on a substrate. A first electrode is connected to the first conductivity type compound semiconductor layer on a surface side of the compound semiconductor layers. The second conductivity type compound semiconductor layer is exposed by partly etch-removing a portion of the compound semiconductor layers. A second electrode is provided in electric connection with the exposed second conductivity type compound semiconductor layer. Said first and second electrodes are formed such that current provided at a suitable voltage across said first and second electrodes uniformly spreads through an entire active light emitting layer, leading to the light emitting element being uniform in brightness and long in service life.

### BACKGROUND OF THE INVENTION

1. Field of the Invention

This invention generally relates to a light-emitting element, and particularly, the present invention relates to a gallium nitride-based light-emitting element and a method of manufacturing the same. More particularly, the present invention relates to a structure and a method for manufacturing electrodes for such a light-emitting element.

2. Description of the Related Art

Many types of light emitting elements are used in a wide range of applications. In particular, gallium nitride-based compound semiconductors have attracted a great deal of attention because of their capability to emit lights in colors of red, green, blue and UV with great stability and strong intensity.

In this invention, “gallium nitride-based compound semiconductor” means a nitride semiconductor of a Group III element containing gallium, such as GaN, GaAlN, InGaN, or InAlGaN. Such a compound semiconductor may be represented by the formula:

InₓAl_{y}G_{1-x-y}N

Where, 1≧x≧0, 1≧x≧0, and 1≧x+y≧0

Generally, a light-emitting element is manufactured by growing gallium nitride-based compound semiconductor layers on a sapphire substrate 1, as schematic exemplary view in FIG. 1. Said element usually includes a first conductivity compound semiconductor layer doped by a donor impurity (n-type cladding layer) 2, an active light-emitting layer 4 formed of a material having a band-gap energy lower than that of said cladding layers, such as an InGaN-based (having In and Ga variable in ratio thereof) compound semiconductor, and a second conductivity compound semiconductor layer doped by an acceptor impurity (p-type cladding layer) 3.

Since sapphire is an insulator, electrodes of said light-emitting element can not be formed on said substrate side. Therefore, said electrodes must be located on said compound semiconductor layer side.

In the prior art by referring to FIG. 2A, a first electrode (a p-type electrode) 6 is provided on the surface of the semiconductor layers. The p-type cladding layer 3 and the active light-emitting layer 4 are partially removed by a conventional etching method to expose a portion of the n-type cladding layer 2. A second electrode (n-type electrode) 5 is formed on the exposed portion of said n-type cladding 5. Said electrode 5 and 6 in general are formed in a circular or rectangular shape in plan, as shown in FIG. 2B.

When a suitable voltage provides across the electrode 5 and 6, current flows from the electrode 6 laterally through the p-type cladding layer 3 to a randomly assigned point A in FIG. 2B, down vertically through active light-emitting layer 4, in which light emits, to the n-type cladding layer 2, and finally laterally towards the electrode 5. Apparently, said light emitting at said point A relays on lateral current spreading in both said cladding layers 2 and 3. Gallium-nitride based compound semiconductors employed in making light-emitting elements is high in electric resistance due to difficulties in effective doping of the gallium-nitride based compound semiconductors. Impurities used for p-type doping (p-type dopants) of the gallium-nitride based compound semiconductors are much poorer in their incorporation capabilities than those used for n-type doping (n-type dopants). Thus the p-type dopants cannot be sufficiently introduced to the gallium-nitride based compound semiconductors. Comparing to the n-type dopants, ionization energies of the p-type dopants are much higher than the n-type dopants in the gallium-nitride based compound semiconductors. Eventually, a p-type cladding layer has a much higher electric resistance than an n-type cladding layer 2. Hence, a series resistance between the electrode 5 and 6 for the path A as demonstrated in FIG. 2A and FIG. 2B is dominated by the electric resistance of current flowing through the p-type cladding layer 3. In general, a series resistance between the electrode 5 and 6 in FIG. 2B prominently increases as the distance between a light-emitting point and said p-type electrode 8 increases. More typically referring to FIG. 2C, the path A has a greater series resistance than the path B. This eventually leads to current flow concentrates in said path B. In other words, more intensive light emits locally over a region around said electrode 6. The active light-emitting layer 4 has its electric current unevenly flowing therethrough, resulting in uneven light emission.

So that, it is preferred that electric current flows spreading through an active light-emitting layer 4 as broad as possible at its plane. In order to ensure uniform spreading of provided current over entire said active layer 4, a first electrode 7 can be formed substantially over a p-type cladding layer, as shown in FIG. 3A and FIG. 3B. Said electrode 7 provides ohmic contacting to said p-type cladding layer. More importantly said electrode 7 itself provides a conductive layer for a broad current spreading. An even light emitting over entire said active light-emitting layer 4 occurs.

The electrode 7 is a metallic-layer with a substantial thickness in order to be conductive enough for a broad current spreading. Said electrode 7 is therefore not light-transmissive. So, emitted light has to be taken out on the side of a substrate, which is opposite to the side on which the compound semiconductor layers are formed. When a light emitting element is mounted on a lead frame, the electrodes 5 and 7 on the compound semiconductor layer side must contact lead frames. This configuration introduces great difficulties to reduce the size of a light emitting element, because the electrode 5 and 7 must be spaced apart sufficiently in order to avoid electrical short-circuit between said electrode 5 and 7.

In the prior art, a thin light-transmissive layer 8 provides substantially over a p-type cladding layer 3 instead of a thick electrode 7 (see FIG. 4A). An electrode 5 is placed to a cut-away corner portion of an n-type cladding layer. An electrode 9 mainly for electric connection to said light-transmissive layer 8 is placed to a corner portion. Normally said electrode 9 is placed to a corner portion the farthest from said cut-away corner portion for said electrode 5, as shown in FIG. 4B.

Comparing to very poor conductivity of a p-type cladding layer, the light-transmissive layer 8 not only improves uniformity of current spreading over an entire active layer 4 but also allows a light-emitting elements to be mounted in the way that a gallium nitride-based compound semiconductor side faces up. The restrictions arising from mounting a light-emitting element in the way of facing said gallium nitride-based compound semiconductor side down releases. The light-transmissive layer 8 reduces a series resistance of electric current flowing through said p-type cladding layer. This improves uniformity of current spreading over said active light-emitting layer 4 once a suitable voltage provides across said electrode 5 and 9.

The term “light-transmissive” with respect to an electrode means that the electrode transmits usually transmits 20 to 40% or more of the light emitted from the element therethrough. The light transmission and the electric resistance of the light-transmissive layer 8 are in a reciprocal relation. In order to do so, the light-transmissive layer 8 has to maintain its thickness as thin as a few tens of manometers in total. So that, the presence of said light-transmissive layer 8 improves current spreading laterally, but it is impossible to reduce the electric resistance to a negligible extent. Moreover, an n-type cladding layer 2 usually has orders of magnitude higher in electric conductivity than a p-type cladding layer 3. As a result, the series resistance of current flowing through an randomly assigned point A in FIG. 4B is still dominated by the distance of current flowing from said electrode 9 to said point A through a light-transmissive layer 8 The resistance contributed by the current flowing through the n-type cladding layer 2 is negligible unless a long distance of current flowing through said n-type cladding layer occurs. Hence non-uniform current spreading presents over an entire light-emitting layer 4 due to variable series resistance caused by different distances of light-emitting points to said p-type electrode 9.

To this end, there is a problem that a first electrode on a light-transmissive layer needs to be arranged in a manner keeping all the light-emitting points on a light-emitting element having their distances of electric current paths flowing through a light-transmissive layer to be as identical as possible.

### SUMMARY OF THE INVENTION

The present invention has been developed in order to remove the above-mentioned disadvantages and drawbacks inherent to the known electrodes used in known light-emitting elements.

It is, therefore, a primary object of the present invention to provide an electrode with arm-like legs extending from said electrode to improve uniformity of current spreading over an entire active light-emitting layer in a plane.

Another object of the present invention is to provide a method of manufacturing a large light-emitting element, in which uniformity of provided electric current spreading over an entire active light-emitting layer in a plane maintains.

A still further object of the present invention is to provide a method of manufacturing gallium nitride-based compound semiconductor light-emitting elements in which uniformity of brightness over an entire light-emitting layer is improved and reliability of light-emitting element is enhanced.

In accordance with the present invention, a compound semiconductor light emitting element has compound semiconductor layers including a first conductivity type compound semiconductor layer and a second conductivity type compound semiconductor layer formed on a substrate. A first electrode is connected to the first conductivity type compound semiconductor layer on a surface side of the compound semiconductor layers. The second conductivity type compound semiconductor layer is exposed by partly etch-removing a portion of the compound semiconductor layers. A second electrode is provided in electric connection with the exposed second conductivity type compound semiconductor layer. Here, the “first conductivity type” and the “second conductivity type” means that when either one of the polarities for a semiconductor, i.e. p-type and n-type, is taken as a first conductive type, the other polarity is considered as a second conductivity type.

The element may be constituted by that a light-transmissive layer is formed at substantially an entire surface of the semiconductor layer thereof on which the first electrode is provided. Said light-transmissive layer facilitates current spreading uniformly into said first conductivity type semiconductor layer in a plane. Here, the “substantially an entire surface” means to provide a light-transmissive layer over a broad area in the surface of the semiconductor layers to cause spread in electric current flow to a sufficient extent, involving also the case that the light-transmissive layer is formed not completely covering end portions of the same surface in order to prevent against electric shorting.

Said substrate is preferably formed in a rectangular or a square form in plan. The first and second electrodes are not preferably both placed along one side in a plan form of the substrate. It is preferable to place the first electrode along one side and the second electrode along the opposite side in a plan form of the substrate. It is also preferable to place the first electrode to a corner portion on said side in a plan form of the substrate and the second electrode at a portion around geometric center of said light-transmissive layer in plan. This also involves the case that the electrodes are formed not completely covering end portions of the same surface in order to prevent against electric shorting.

In form of the present invention, said first electrode has arm-like legs extending from said first electrode to facilitate electric current uniformly over an entire active light-emitting layer without concentration at a particular location. Here, the “electrodes” means electrode portions (electrode pads) formed thick for enabling wire bonding thereto.

For a better understanding of the nature and advantages of the present invention, reference should be made to detailed description taken in conjunction with accompanying drawings.

### BRIEF DESCRIPTION OF THE DRAWINGS

These and other objects and features of the present invention will be more readily apparent from the following detailed description of the preferred embodiments taken in conjunction with the accompanying drawings in which:

FIG. 1A is a cross-sectional view of a known-gallium nitride-based light-emitting element without any metallic layers on the top surface;

FIG. 2A is a cross-sectional view of a known-gallium nitride-based light-emitting element (Dashed lines are the guide-to-eye, schematically showing the current path);

FIG. 2B is a top view of a known-gallium nitride-based light-emitting element (Dashed lines are the guide-to-eye, schematically showing the current path);

FIG. 3A is a cross-sectional view of another known-gallium nitride-based light-emitting element (Dashed lines are the guide-to-eye, schematically showing the current path);

FIG. 3B is a top-view of another known-gallium nitride-based light-emitting element (Dashed lines are the guide-to-eye, schematically showing the current path);

FIG. 4A is a cross-sectional view of another further known-gallium nitride-based light-emitting element;

FIG. 4B is a top-view of another further known-gallium nitride-based light-emitting element;

FIG. 5A is a cross-sectional view of a first embodiment of a gallium nitride based light-emitting element according to the present invention;

FIG. 5B is a top-view of a first embodiment of a gallium nitride based light-emitting element according to the present invention;

FIG. 6 is a top-view of a second embodiment of a gallium nitride based light-emitting element according to the present invention;

FIG. 7 is a top-view of a third embodiment of a gallium nitride based light-emitting element according to the present invention;

FIG. 8 is a top-view of a forth embodiment of a gallium nitride based light-emitting element according to the present invention;

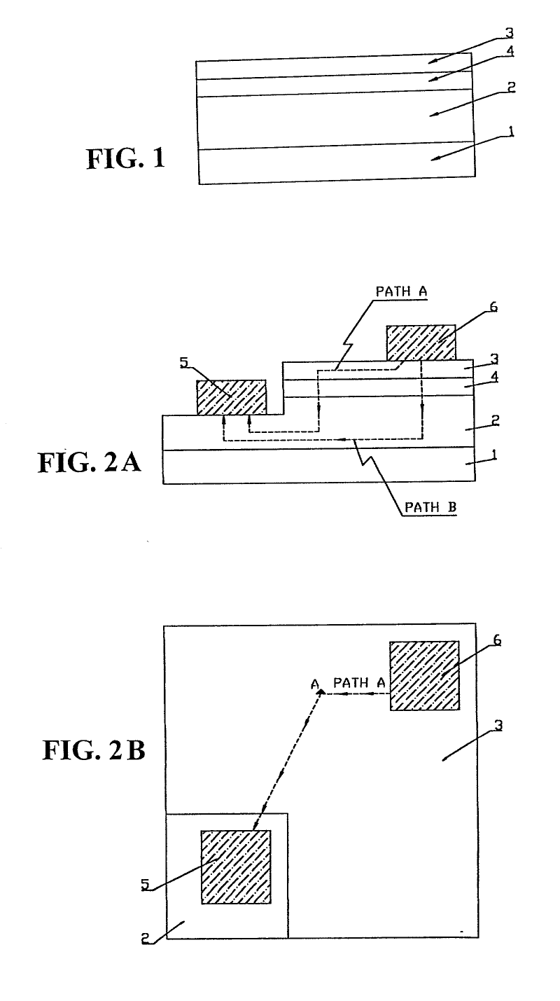

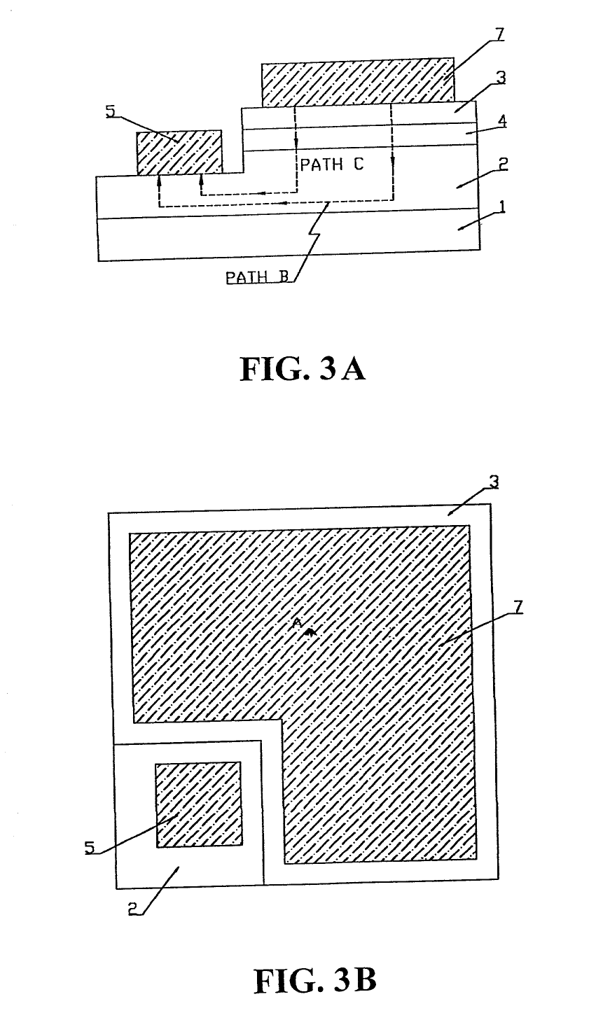

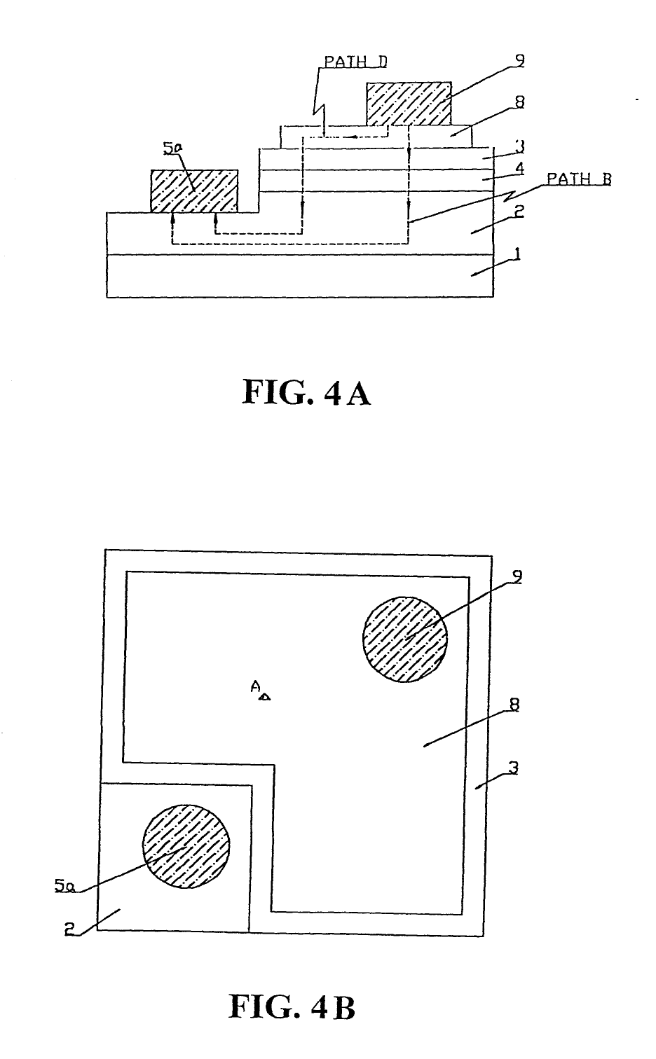

### DETAILED DESCRIPTION OF THE PREFERRED EMBODIMENTS

The present invention will now be described below in detail with reference to the accompanying drawing FIGURES. Throughout the FIGURES, the same parts or portions are denoted by the same reference numerals.

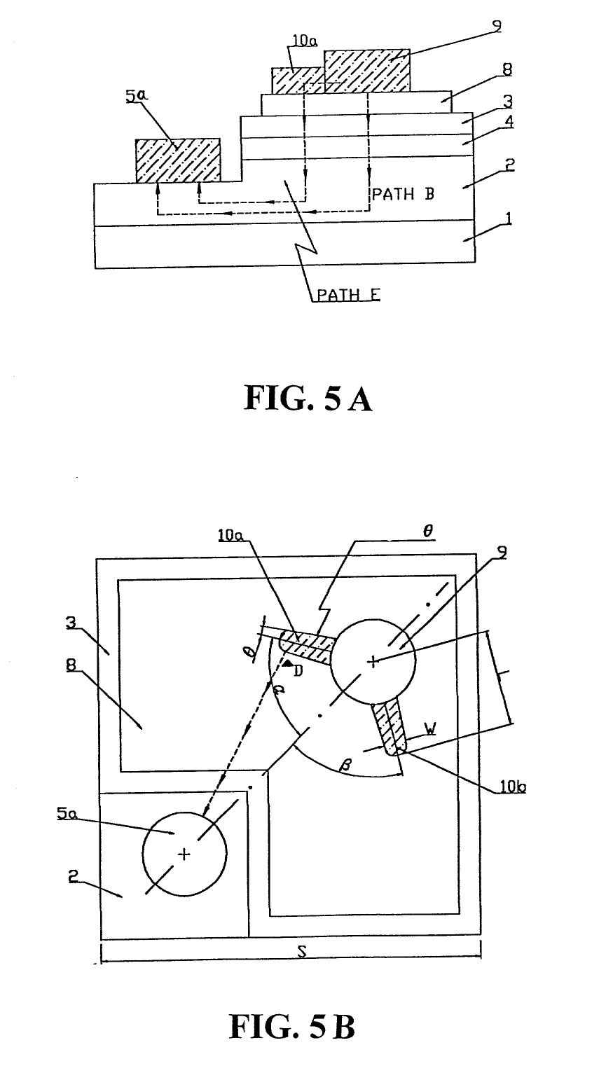

FIG. 5A and FIG. 5B schematically show a gallium nitride-based compound semiconductor light-emitting element according to a first embodiment of the present invention.

The light-emitting element has a transparent and electrically insulating substrate 1, such as sapphire or the like. An n-type gallium nitride-based compound semiconductor layer (n-type cladding-layer) 2 is formed on a surface of the substrate 2. The n-type cladding-layer 2 is doped with an n-type dopant, such as silicon (Si), germanium (Ge), selenium (Se), sulfur (S) or tellurium (Te). On the surface of the n-type cladding-layer 2, an active light-emitting layer 4 is formed. The active light-emitting layer 4 is made of a single quantum well or multiple quantum wells of InGaAlN/InGaAlN (SQW or MQWs) having a band-gap energy lower than that of said cladding layers. A p-type gallium nitride-based compound semiconductor layer (p-type cladding-layer) 3 is formed on the other surface of said active light-emitting layer 4. The p-type cladding-layer 3 is doped with a p-type dopant, such as beryllium (Be), strontium (Sr), barium (Ba), zinc (Zn) or magnesium (Mg).

For a simple p-n junction structure, said active light-emitting layer can be replaced by a direct interface of said n-type and p-type cladding layers. Said light-emitting element has a planar top shape with four-comers, preferably in a square shape in plan.

The p-type cladding-layer 3 is partially etched away, together with a surface portion of the n-type cladding-layer 2, to partially exposing the surface of the n-type cladding-layer 2. An n-electrode 5a is formed on the exposed surface portion of the n-type cladding-layer 2. Alight-transmissive layer 8 is formed to directly cover a substantially entire surface of the p-type cladding-layer 3 thereof, on a portion of which another electrode 9 is provided. Said electrode 5a us preferably placed at a corner portion of said square substrate. Said electrode 9 is therefore arranged on positions corresponding to positions between the diagonal corner of said p-type electrode 9 and the geometric center of and said light-transmissive layer 8 of a projected plane of said substrate.

The n-type electrode 5, the p-type electrode 9, and the light-transmissive layer 8 are made of single or multiple layers of metallic elements selecting from among Au, Cr, Ni, Al, Ti, Pd, W, Pt or alloys of said metallic elements using a conventional deposition method. Annealing at elevated temperatures after deposition of said n-type electrode 5, p-type electrode 9 and light-transmissive layer 8 is preferable to reduce their contacting resistance.

The present invention is characterized, as shown in FIG. 5B, for the first embodiment of the semiconductor light-emitting element, by extending two arm-like legs 10a and 10b from said p-type electrode 9 in the opposite direction. The pointing direction of each said arm-like leg is not in parallel to a line of two geometric centers of said n-type electrode 5 and p-type electrode 9 in a plan form of said substrate. Referring to FIG. 5B, the angle, .and ,are preferably in the range of 15°-1650°, more preferably 45-90°. The values of said .and are preferable to be same.

The p-type electrode 9, the n-type electrode 5a, the light-tansmissive layer 7 and the arm-like legs 10a and 10b can be formed into a desired shape by a conventional thin film forming method like a lift-off technique or the similar. The arm-like leg 10a and 10b are preferable to use good conductive metallic elements like Au, Al, Ti, Ni, W, Pt, Pd or alloys of said elements and can be the same metallic layers as used for said n-type or p-type electrode. The arm-like legs 10a and 10b can be deposited at the same time with said n-type or p-type electrode using a conventional method or separately deposited by their own. The thickness of the arm-like leg 10a and 10b is no less than 15 nm, preferably from 150 nm to 2 μm. A relatively thick layer of said arm-like legs 10a and 10b ensures a good conductivity provided.

The areas of said n-type electrode 5 and p-type electrode 9 are satisfactory for performing bonding. So that, it is preferred that the area on the n-type electrode 5 is made small so as to increase the area on the side of the light-transmissive layer 8, which provides on the semiconductor layers including the active light-emitting layer 4. Since the p-type electrode 9 is thick for performing bonding, hence said p-type electrode 9 is not light transmissive. The area of said p-type electrode 9 is also made small so as to maximize the area for the light-transmissive layer 8 on the semiconductor layers. The shape of said electrode 9 and 5 is preferably in square or circular in plan, more preferably in circular with the diameter not less than 50 μm in a plan form of said substrate.

Depending on the thickness of the arm-like leg 10a and 10b as well as the types of metallic elements used for said arm-like leg 10a and 10b, the arm-like leg 10a and 10b may not be light transmissive. Hence it is preferable to minmize the area covered by said arm-like leg 10a and 10b. Referring to the configuration of FIG. 5B, the width W of the arm-like leg 10a and 10b is in the range of 0.5 μm to 50 μm, preferably 5 μm to 20 μm.

For each said arm-like leg, it is also preferable to gradually slim said leg in width from the nearest portion to the p-type electrode 9 downward the farthest end of said arm-like leg, as shown in FIG 5B. The slope, ,is in the range of 0.5°-30°, preferably 5°-10°.

The length of each said arm-like leg 10a and 10b extending from the p-type electrode 9 depends on the size and shape of a light-emitting element in plan. For a square shape of a light-emitting element with the length S of each side, the preferable length L measuring from the center of the p-type electrode 9 to the farthest end of said arm-like leg 10a or 10b is from 0.01 S to 0.5 S, more preferably from 0.1 S to 0.25 S.

For a randomly assigned point D in a light-emitting element, provided current laterally flows from the p-type electrode 9 through the arm-like leg 10a and the light-transmissive layer 8 to said point D, then vertically flows down through the active light-emitting layer 4 to the n-type cladding layer 2 and the n-type electrode 5. With the provision of said arm-like leg 10a, the distance of current flowing through the said light-transmissive layer 8 reduces, which leads to an improved uniformity of current spreading over said light-transmissive layer 8. Thus, the arm-like legs 10a and 10b facilitate a broad spreading of provided current to an entire light-emitting layer 4 without deterioration in the semiconductor layers due to partial concentration of current and hence partial unevenness in brightness.

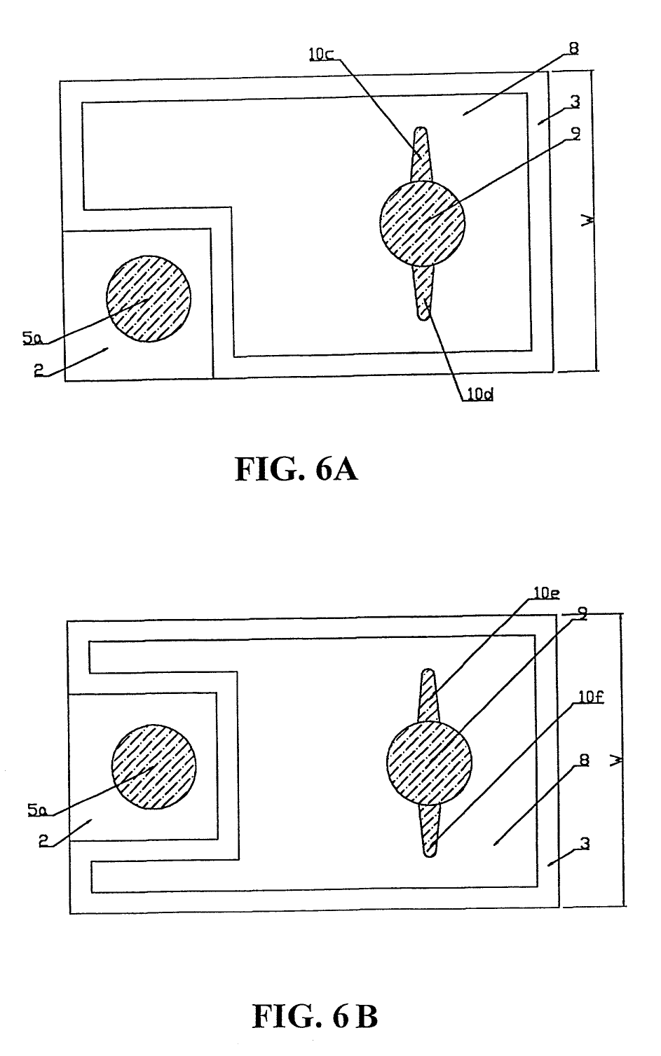

In the above-described first embodiment, the uniformity of current spreading provides for small sizes of light-emitting elements, more preferably for said light-emitting element having a square shape or a rectangular shape that has the length to width ratio less than 1.5. For a light-emitting element having a rectangular shape with the length to width ratio more than 1.5 in plan, a second embodiment is schematically shown in FIG. 6A and FIG. 6B according to the present invention. In the FIG. 6A and FIG. 6B example, the plan shape of a light-emitting element is not square but rectangular so that the p-type electrode 9 and the n-type electrode 5a are separately placed in a lengthwise direction of the rectangular form.

Preferably, an n-type electrode 5a is placed on partially exposing the surface of the n-type cladding-layer 2 after the p-type cladding-layer 3 being partially etched away, together with a surface portion of the n-type cladding-layer 2, along one side normal to said lengthwise direction. It is more preferable to place the n-type electrode 5 on one corner portion (see FIG. 6A) and further more preferably on a middle portion of said side (see FIG. 6B).

A light-transmissive layer 8 is formed to directly cover a substantially entire surface of the p-type cladding-layer 3 thereof, on a portion of which another electrode 9 is provided. Said electrode 9 is placed to a portion corresponding to the geometric center of a projected plane of said light-transmissive layer 8. Two arm-like legs 10c and 10d in FIG. 6A or 10e and 10f in FIG. 6B extend from said p-type electrode 9 in the direction normal to said lengthwise direction. The length of each said arm-like leg 10c and 10d in FIG. 6A or 10e and 10f in FIG. 6B extending from the geometric center of said p-type electrode 9 depends on the width W of said rectangular substrate in plan. The preferable length, measuring from the center of the p-type electrode 9 to the farthest end of said arm-like leg 10c or 10d in FIG. 6A or 10e and 10f in FIG. 6B, is from 0.01 W to 0.5 W, more preferably from 0.1W to 0.25W.

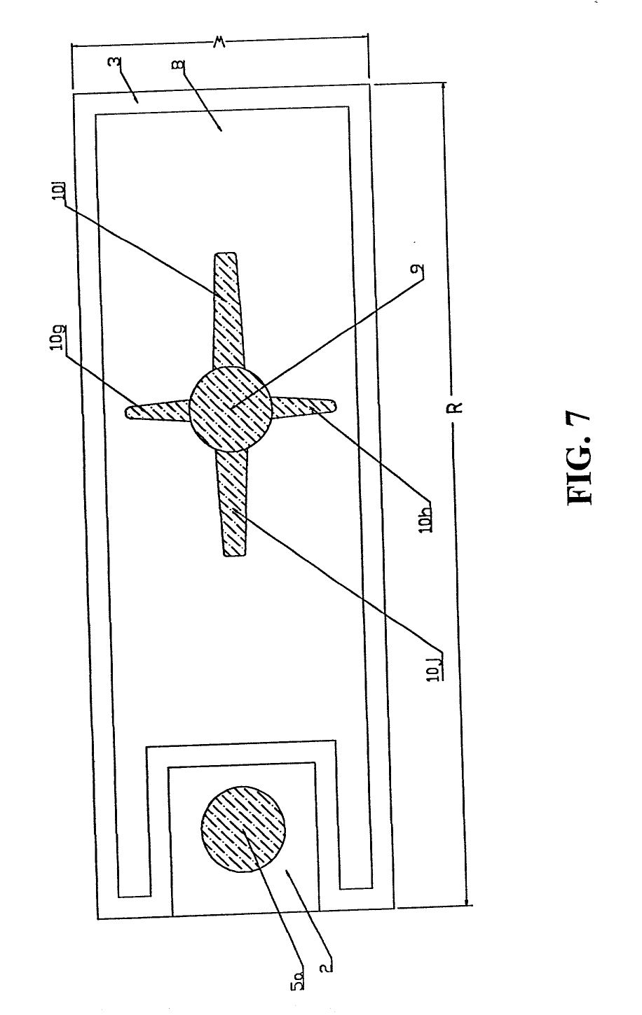

It is preferable to extend another two arm-like leg 10i and 10j in the direction parallel to said lengthwise direction in the case where the length to width ratio of said rectangular substrate in plan is large than 2.5, as shown in FIG. 7, omitting explanations thereof The preferable length, measuring from the center of the p-type electrode 9 to the farthest end of said arm-like leg 10i or 10j, is from 0.01R to 0.5R, more preferably from 0.1R to 0.25R, where R is the length of said rectangular shape in plan of said substrate.

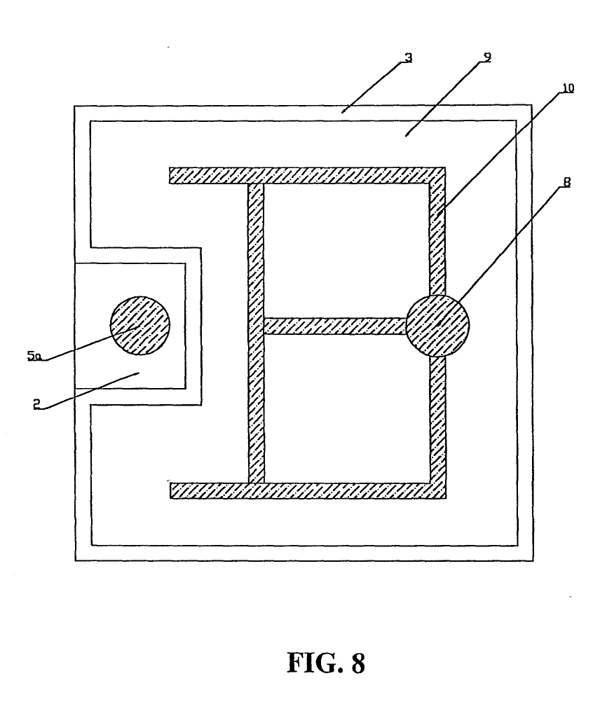

For even a bigger size of said element in a square or rectangular shape in plan, a grid structure as shown in FIG. 8 provides to extend current flows evenly to far portions away from the p-type electrode 9, omitting explanations thereof The grid void is preferable to be in square with the width of approximately 50 μm-1000 μm, preferably 350-500 μm, or in rectangular with the length to width ratio not more than 2 preferably less than 1.5 and the width of approximately 50 μm -1000 μm, preferably 350-500 μm.

According to the present invention, the electric current distribution is uniform within the light emitting element to thereby provide uniform light emission and hence increase light emitting efficiency. Moreover, there is no concentration of currents at particular regions. Therefore, there is no fear that the semiconductor layers are deteriorated at certain regions to shorten service life or results in failure. Although preferred embodiments have been described in some detail, it is to be understood that certain changes can be made by those skilled in the art without departing from the spirit and scope of the invention as defined by the appended claims.

What is claimed is:

1. A semiconductor light emitting element comprising:
a substrate in a square form;
semiconductor layers formed, of a gallium-nitride based compound semiconductors, on said substrate to include a first conductivity type semiconductor layer, and a second conductivity type semiconductor layer;
a first conductivity type semiconductor layer partially etched away, together with a surface portion of a second conductivity type semiconductor layer, to partially exposing the surface of said second conductivity type semiconductor layer at a corner portion in plan of said semiconductor layers;
a light-transmissive layer formed to directly cover a substantially entire surface of first conductivity layer thereof, on a portion of which a first electrode provides;
a second electrode formed in electrical connection with said second conductivity type semiconductor layer;
wherein said first electrode arranged on positions corresponding to positions located between the diagonal corner of said second electrode and the geometric center of and said light-transmissive layer of a projected plane of said substrate;
said first electrodes formed such that said electrodes having two arm-like legs extending from said first electrodes pointing to opposite-directions.

2. The element according to claim 1, wherein said arm-like legs are not in parallel to a line of two geometric centers of said first and second electrode in a plan form of said substrate.

3. The element according to claim 1, wherein said arm-like legs comprise at least one good conductive metal like Au, Al, Ti, Ni, W, Pt, Pd or alloys of said elements.

4. The element according to claim 1, wherein said arm-like legs have thickness no less than 15 nm, preferably from 150 nm to 2 μm.

5. The element according to claim 1, wherein said arm-like legs have widths in the range of 0.5 μm to 50 μm, preferably 5 μm to 20 μm in plan of said element.

6. The element according to claim 1, wherein said arm-like legs have gradually sliming width from the nearest portion to said first electrode downward the farthest end of said arm-like leg. The slimming slope is in the range of 0.5°-30°,preferably 5°-10°.

7. The element according to claim 1, wherein the length of said arm-like legs measuring from the center of said first electrode to the farthest end of said arm-like leg is from 0.01S to 0.5S, more preferably from 0.1S to 0.25S, wherein S is the width of said element in plan.

8. The element according to claim 1, wherein said substrate can be in rectangular with the length to width ratio less than 1.5 in plan of said element.

9.The element according to claim 8, wherein said substrate can be in rectangular with the length to width ratio more than 1.5 but less than 2.5 in plan of said element.

10.The element according to claim 9, wherein said first and second electrode according to claim 1 are placed separately in a length direction of the rectangular form in plan of said element.

11.The element according to claim 9, wherein said second electrode according to claim 1 is placed at a corner portion or a middle portion of one width side of said element.

12.The element according to claim 9, wherein said first electrode according to claim 1 is placed at a portion of the geometric center of said transmissive layer according to claim 1.

13.The element according to claim 12, wherein said first electrode has two arm-like legs extending from the geometric center of said first electrode in opposite directions.

14.The element according to claim 13, wherein the pointing directions of said arm-like legs are in normal to the lengthwise direction of said rectangular substrate.

15.The element according to claim 13, wherein each said arm-like leg has a length measuring from the center of said first electrode to the end of said leg is from 0.01W to 0.5W, more preferably from 01.W to 0.25W, where W is the width of said rectangular substrate in plan.

16.The element according to claim 13, wherein said first electrode has another two arm-like legs extending in opposite directions along the lengthwise direction of said rectangular substrate in plan, in the case where the length to width ratio of said rectangular substrate in plan more than 2.5.

17.The element according to claim 16, wherein each said arm-like leg in the lengthwise direction of said element has a length measuring from the geometric center of said first electrode to the end of said leg is from 0.01R to 0.5R, more preferably from 0.1R to 0.25R, where R is the length of said rectangular substrate in plan.
